(19) United States
(12) Patent Application Publication
(10) Pub. No.: US 2009/0267123 A1
(43) Pub. Date: Oct. 29, 2009

(54) SEMICONDUCTOR DEVICE

(75) Inventors: Soichi YAMAZAKI, Kanagawa-ken (JP); Koji Yamakawa, Tokyo (JP); Masahiro Kiyotoshi, Mie-ken (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/426,509

(22) Filed: Apr. 20, 2009

(30) Foreign Application Priority Data
Apr. 24, 2008 (JP) 2008-114409

(51) Int. Cl. H01L 27/115; H01L 27/108

(52) U.S. Cl. 257/295; 257/296; 257/368; 257/E27.104; 257/E27.084

(57) ABSTRACT

A semiconductor device includes: a semiconductor substrate; a plurality of transistors on the semiconductor substrate, each of the transistors has a source and drain region; an interlayer insulating film on the semiconductor substrate and the plurality of transistors; and at least three capacitors on the interlayer insulation film, each of them has a top electrode, a bottom electrode and an insulating film interposed therebetween; wherein the 1st and 2nd capacitors have an shared electrode, with the top electrodes of the 1st and 2nd capacitors, which has a 1st longer direction, the 2nd and 3rd capacitors have an shared electrode, with the bottom electrodes of the 2nd and 3rd capacitors, which has a 2nd longer direction different from the 1st direction.

### CROSS REFERENCE TO RELATED APPLICATION

This application is based upon and claims the benefit of priority from Japanese Patent Application No. 2008-114409, filed on Apr. 24, 2008, the entire contents of which are incorporated herein by reference.

### BACKGROUND

As a conventional semiconductor device, there is known a ferroelectric memory having a chain structure in which memory cells each including a ferroelectric capacitor and a transistor connected in parallel are arranged in a chain-like manner.

According to this semiconductor device, it is possible to share a capacitor drive line with multiple memory cells and thereby to reduce an area occupied by the memory cells.

Meanwhile, a ferroelectric random access memory (FeRAM) employing a three-dimensional capacitor structure is known as another conventional semiconductor device.

According to this semiconductor device, by forming the three-dimensional capacitor structure, it is possible to ensure a sufficient charge storage area for obtaining a signal amount necessary for operating the device and to reduce an area occupied by capacitor cells, and thus to reduce an area occupied by memory cells.

### SUMMARY

Aspects of the invention relate to an improved semiconductor device.

In one aspect of the present invention, a semiconductor device may include a semiconductor substrate; a plurality of transistors on the semiconductor substrate, each of the transistors has a source and drain region; an interlayer insulating film on the semiconductor substrate and the plurality of transistors; and at least three capacitors on the interlayer insulation film, each of them has a top electrode, a bottom electrode and an insulating film interposed therebetween; wherein the 1st and 2nd capacitors have an shared electrode, with the top electrodes of the 1st and 2nd capacitors, which has a 1st longer direction, the 2nd and 3rd capacitors have an shared electrode, with the bottom electrodes of the 2nd and 3rd capacitors, which has a 2nd longer direction different from the 1st direction.

In another aspect of the invention, a semiconductor device may include a semiconductor substrate; a plurality of transistors arranged in series in a predetermined direction on the semiconductor substrate with source-drain regions shared by the mutually adjacent transistors; an interlayer insulating film formed on the semiconductor substrate and the plurality of transistors; a first capacitor electrode including a plurality of electrodes arranged above the interlayer insulating film in one row at predetermined distances in a direction substantially parallel to the predetermined direction; a second capacitor electrode including a plurality of electrodes arranged above or below the first capacitor electrode with a capacitor insulating film interposed therebetween in two rows in a zigzag manner at predetermined distances in a direction substantially parallel to the predetermined direction; a first capacitor contact connecting the first capacitor electrode to one of the source-drain regions; and a second capacitor contact connecting the second capacitor electrode to another one of the source-drain regions, wherein each of the electrodes in one row out of the two rows of the second capacitor electrode is formed above or below part of the 2n-th electrode and part of the 2n+1-th electrode, from one end, out of the electrodes of the first capacitor electrode, and each of the electrodes in the other row out of the two rows of the second capacitor electrode is formed above or below part of the 2n-th electrode and part of the 2n+1-th electrode, from the one end, out of the electrodes of the first capacitor electrode, where n is a positive integer.

### BRIEF DESCRIPTIONS OF THE DRAWINGS

A more complete appreciation of the invention and many of the attendant advantages thereof will be readily obtained as the same becomes better understood by reference to the following detailed description when considered in connection with the accompanying drawings.

FIG. 1 is a top view of a semiconductor device in accordance with a first embodiment of the present invention.

FIG. 2 is a cross sectional view of a semiconductor device in accordance with a first embodiment of the present invention at the cutting plane in chain line II-II of FIG. 1.

FIG. 3 is a cross sectional view of a semiconductor device in accordance with a first embodiment of the present invention at the cutting plane in chain line III-III of FIG. 1.

FIG. 4 is a cross sectional view of a semiconductor device in accordance with a first embodiment of the present invention at the cutting plane in chain line IV-IV of FIG. 1.

FIG. 5 is a top view of a semiconductor device in accordance with a first embodiment of the present invention.

FIG. 6 is a cross sectional view of a semiconductor device in accordance with a first embodiment of the present invention.

FIG. 7A is a top view of a semiconductor device in accordance with a second embodiment of the present invention.

FIG. 7B is a top view of a semiconductor device in accordance with a second embodiment of the present invention.

FIG. 8 is a cross sectional view of a semiconductor device in accordance with a third embodiment of the present invention.

FIG. 9 is a top view of a semiconductor device in accordance with a fourth embodiment of the present invention.

FIG. 10 is a cross sectional view of a semiconductor device in accordance with a fourth embodiment of the present invention at the cutting plane in chain line X-X of FIG. 9.

FIG. 11 is a cross sectional view of a semiconductor device in accordance with a fourth embodiment of the present invention at the cutting plane in chain line XI-XI of FIG. 9.

FIG. 12 is a cross sectional view of a semiconductor device in accordance with a fourth embodiment of the present invention at the cutting plane in chain line XII-XII of FIG. 9.

FIG. 13 is a top view of a semiconductor device in accordance with a fourth embodiment of the present invention.

FIG. 14 is a top view of a semiconductor device in accordance with a fourth embodiment of the present invention.

### DETAILED DESCRIPTION

Various connections between elements are hereinafter described. It is noted that these connections are illustrated in general and, unless specified otherwise, may be direct or indirect and that this specification is not intended to be limiting in this respect.

Embodiments of the present invention will be explained with reference to the drawings as next described, wherein like reference numerals designate identical or corresponding parts throughout the several views.

### First Embodiment

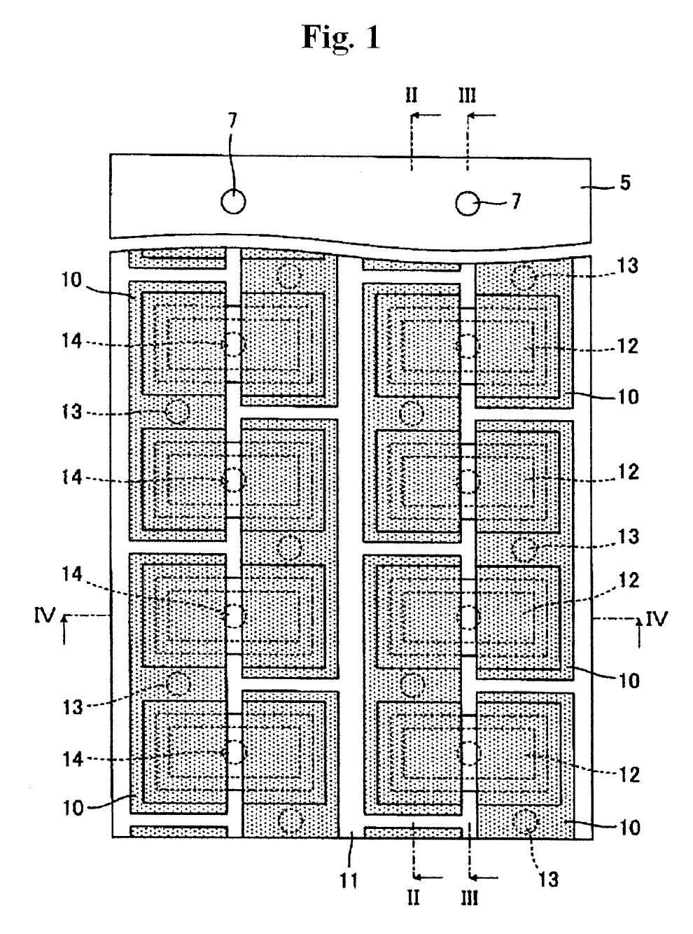

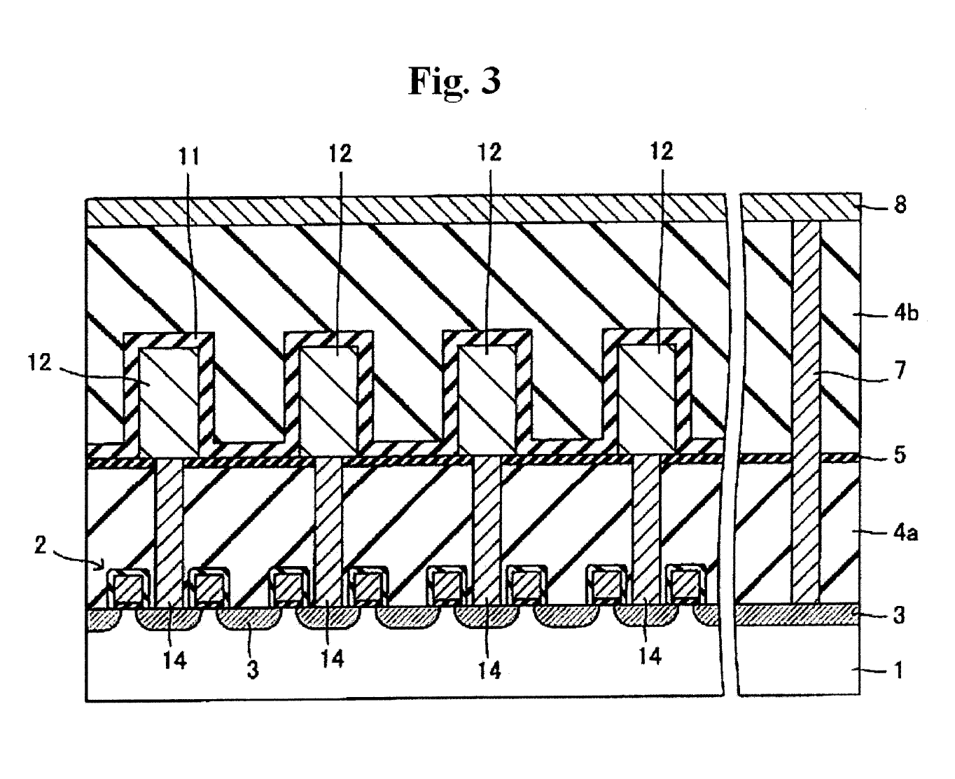

A first embodiment of the present invention will be explained hereinafter with reference to FIGS. 1-6.

(Configuration of Semiconductor Device)

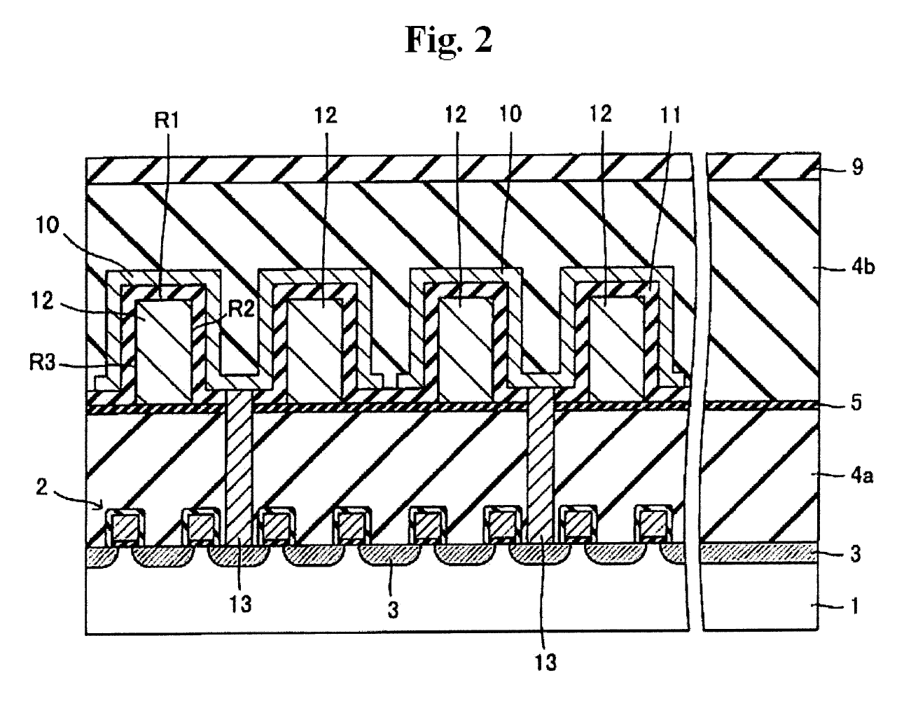

FIG. 1 is a top view showing a capacitor structure of a semiconductor device according to a first embodiment of the present invention. Meanwhile, FIGS. 2 to 4 are cross-sectional views showing cross sections that are respectively taken along chain lines II-II, III-III, and IV-IV in FIG. 1 and viewed from directions of arrows attached thereto.

A semiconductor device according to this embodiment is a ferroelectric random access memory (FeRAM) having a chain structure, which includes: a semiconductor substrate 1; multiple transistors 2 that are arranged in series in a predetermined direction with source-drain regions 3 shared by the mutually adjacent transistors; an interlayer insulating film 4a formed on the semiconductor substrate 1 and the transistors 2; a cap layer 5 formed on the interlayer insulating film 4a; capacitor lower electrodes 12 formed on the cap layer 5; capacitor upper electrodes 10 formed on the capacitor lower electrodes 12 with a capacitor insulating film 11 interposed therebetween; capacitor contacts 13 for connecting the capacitor upper electrodes 10 to one of the source-drain regions 3; capacitor contacts 14 for connecting the capacitor lower electrodes 12 to the other one of the source-drain regions 3; an interlayer insulating film 4b formed on the cap layer 5, the capacitor upper electrodes 10, and the capacitor insulating film 11; bit lines 8 formed on the interlayer insulating film 4b and connected to drain ends of the source-drain regions 3 via bit line contacts 7; and an inter-wiring insulating film 9 formed between the bit lines 8 on the interlayer insulating film 4b.

The semiconductor substrate 1 is made of a Si-based single crystal such as single-crystal Si.

Each transistor 2 includes: a gate insulating film formed on the semiconductor substrate 1; a gate electrode formed on the gate insulating film; an insulating film to cover an upper surface and a side surface of the gate electrode; and the source-drain regions 3 formed on both sides of the gate electrode in the semiconductor substrate 1.

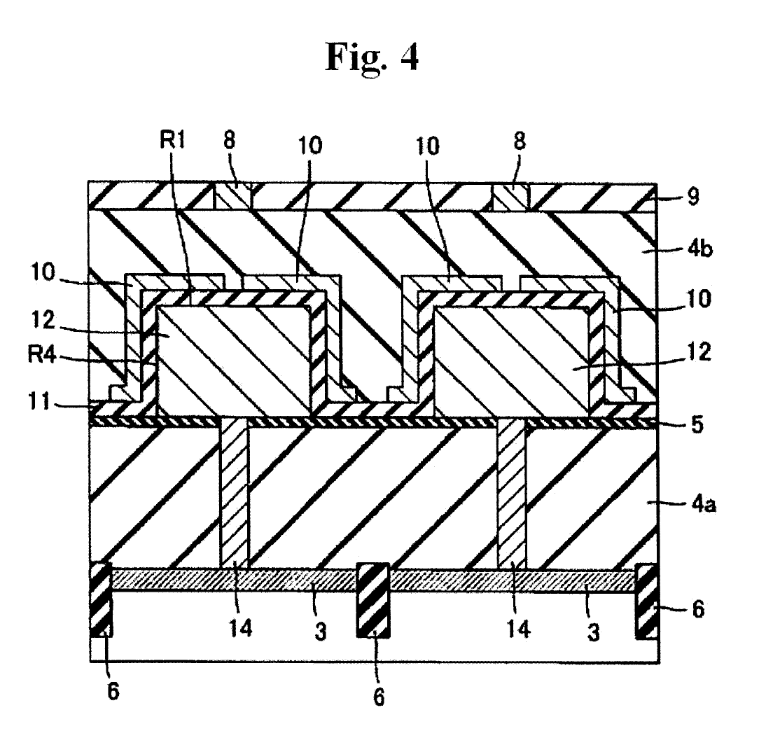

The source-drain regions 3 are formed by implanting conductive impurities into a surface of the semiconductor substrate 1 by use of ion implantation, for example. As for the conductive impurities, B, BF2, In, and the like are used as p-type impurities while As, P, and the like are used as n-type impurities. Meanwhile, as shown in FIG. 4, the source-drain regions 3 are isolated from adjacent element regions by element isolation regions 6.

Each element isolation region 6 is made of an insulative material such as SiO₂ and has a shallow trench isolation (STI) structure.

Each of the interlayer insulating films 4a and 4b is made of an insulating film such as SiO₂, SiN or Al₂O₃. The cap layer 5 is made of an insulating film such as SiN. Meanwhile, the inter-wiring insulating film 9 is made of an insulating film such as SiO₂ or Al₂O₃.

The capacitor lower electrodes 12 are made of a conductive material such as Ir, IrO₂, Ru, RuO₂ or Pt. Alternatively, the capacitor lower electrodes 12 may employ a lamination structure including any of combinations of Ir and TiAlN, Ir and TiSiN, Ir and TaAlN, and the like. Meanwhile, the capacitor lower electrodes 12 are made by forming a material film using a sputtering method, a chemical vapor deposition (CVD) method, a plating method or the like and then patterning the material film using a photolithography method, a reactive ion etching (RIE) method or the like.

The capacitor lower electrodes 12 include multiple electrodes that are arranged in one row at predetermined distances in a direction substantially parallel to the direction of arrangement of the transistors 2 (the vertical direction in FIG. 1). Meanwhile, a lateral direction of each of the capacitor lower electrodes 12 is preferably set substantially the same as the direction of arrangement of the capacitor lower electrodes 12. Here, the capacitor contacts 13 are formed between the mutually adjacent capacitor lower electrodes 12. Accordingly, the above-mentioned predetermined distance (the distance between the mutually adjacent capacitor lower electrodes 12) is greater than a diameter of each capacitor contact 13.

The capacitor upper electrodes 10 are made of a conductive material such as Pt, Ir or IrO₂. Alternatively, the capacitor upper electrodes 10 may employ a lamination structure including any of combinations of strontium ruthenium oxide (SRO) and Pt, SRO and Ir, SRO and IrO₂, SRO and Ir and IrO₂, and the like. Meanwhile, the capacitor upper electrodes 10 are made by forming a material film using the sputtering method, the chemical vapor deposition (CVD) method, the plating method or the like and then patterning the material film using the photolithography method, the reactive ion etching (RIE) method or the like.

The capacitor upper electrodes 10 include multiple electrodes that are arranged on the capacitor lower electrodes 12 with the capacitor insulating film 11 interposed therebetween in two rows in a zigzag manner at predetermined distances in the direction substantially parallel to the direction of arrangement of the transistors 2 (the vertical direction in FIG. 1). Meanwhile, a direction of straight side of each of the capacitor upper electrodes 10 is preferably set substantially the same as the direction of arrangement of the capacitor upper electrodes 10.

The respective electrodes in one row out of the two rows of the capacitor upper electrodes 10 are formed above part of the electrodes disposed in a 2n-th (n is a positive integer) line and part of the electrodes disposed in a 2n−1-th line from one end out of the capacitor lower electrodes 12. Meanwhile, the respective electrodes in another row out of the two rows of the capacitor upper electrodes 10 are formed above part of the electrodes disposed in the 2n-th line and part of the electrodes disposed in a 2n+1-th line from the end out of the capacitor lower electrodes 12.

Specifically, each of the capacitor upper electrodes 10 forms each capacitor cell between the two adjacent capacitor lower electrodes 12. Meanwhile, each of the capacitor lower electrodes 12 forms each capacitor cell between the two adjacent capacitor upper electrodes 10. In this way, an array structure of the capacitor cells forms a chain structure in which the capacitor cells are connected in a zigzag manner.

Therefore, the n-th (1st) and n+1-th (2nd) capacitors have an shared electrode, with the top electrodes of the n-th and n+1-th capacitors, which has a 1st longer direction, the n+1-th and n+2-th capacitors have an shared electrode, with the bottom electrodes of the n+1-th and n+2-th capacitors, which has a 2nd longer direction different from the 1st direction.

Moreover, each of the capacitor upper electrodes 10 is formed at least on a first region R1 which occupies part of upper surfaces of the two adjacent capacitor lower electrodes 12 and on a second region R2 which occupies part of mutually opposed side surfaces of the two adjacent electrodes with the capacitor insulating film 11 interposed therebetween. Here, in order to ensure a larger charge storage area of the capacitor, each of the capacitor upper electrodes 10 is preferably formed on the first region R1, the second region R2, a third region R3 which occupies part of a side surface on the other side of the side surface that includes the second region R2, and a fourth region R4 which occupies a side surface adjacent to the first to third regions R1 to R3 with the capacitor insulating film 11 interposed therebetween as illustrated in FIGS. 1 to 4.

The capacitor insulating film 11 is made of a ferroelectric material such as lead zirconium titanate (PZT) and formed using the CVD method, the sputtering method or the like. Moreover, the capacitor insulating film 11 is integrally formed in the entire regions on the cap layer 5 and the capacitor lower electrodes 12 within a capacitor cell region.

Each of the capacitor contacts 13 and 14 and the bit line contacts 7 is made of a conductive material such as W or polycrystalline Si. Alternatively, the capacitor contacts 13 and 14 and the bit line contacts 7 may employ a multilayer structure using different materials such as a two-layered structure in which an upper layer is made of W while a lower layer is made of polycrystalline Si. Note that a barrier layer made of a Ti film, a laminated film of Ti and TiN or the like may be formed around a position made of a metallic material such as W.

The capacitor contacts 13 are connected to lower surfaces of the capacitor upper electrodes 10 located between the mutually adjacent capacitor lower electrodes 12. Meanwhile, the capacitor contacts 14 are formed on lower surfaces of the capacitor lower electrodes 12.

The bit lines 8 are made of a conductive material such as Cu, Al or an alloy of Al and Cu.

### Effects of First Embodiment

According to the first embodiment of the present invention, by forming each capacitor cell including the capacitor upper electrode 10, the capacitor insulating film 11, and the capacitor lower electrode 12 into a three-dimensional structure, it is possible to ensure a sufficient charge storage area for obtaining a signal amount necessary for operating a device and to reduce an area to be occupied by the capacitor cells. As a result, the space occupied by the memory cells can be reduced as compared with the case of a ferroelectric memory employing a chain structure which includes capacitor cells employing a conventional two-dimensional structure.

Moreover, the directions of straight side of the capacitor upper electrode 10 and the capacitor lower electrode 12 are arranged to define a right angle, and the array structure of the capacitor cells is formed into the zigzag-shaped chain structure. In this way, both the distances between the adjacent bit line contacts 7 and the distances between the bit lines 8 can be reduced as compared with the case of employing a straight chain structure, and thereby capacitance between the bit lines can be suppressed.

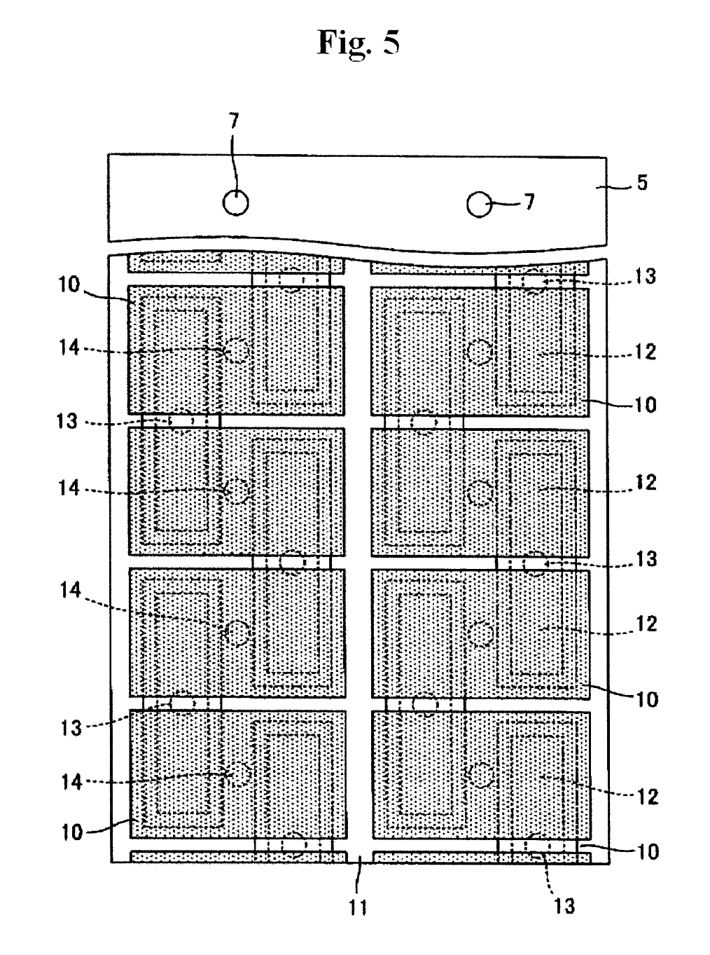

Note that, the layout correlation between the capacitor upper electrodes 10 and the capacitor lower electrodes 12 may be inverted as shown in FIG. 5. Specifically, the multiple electrodes constituting the capacitor lower electrodes 12 are arranged in two rows in a zigzag manner at predetermined distances in the direction substantially parallel to the direction of arrangement of the transistors 2 (the vertical direction in FIG. 5). Meanwhile, the multiple electrodes constituting the capacitor upper electrodes 10 are arranged in parallel in one row at predetermined distances in the direction substantially parallel to the direction of arrangement of the transistors 2 on the capacitor upper electrodes 10 with the capacitor insulating film 11 interposed therebetween. Incidentally, FIG. 5 is a top view corresponding to FIG. 1.

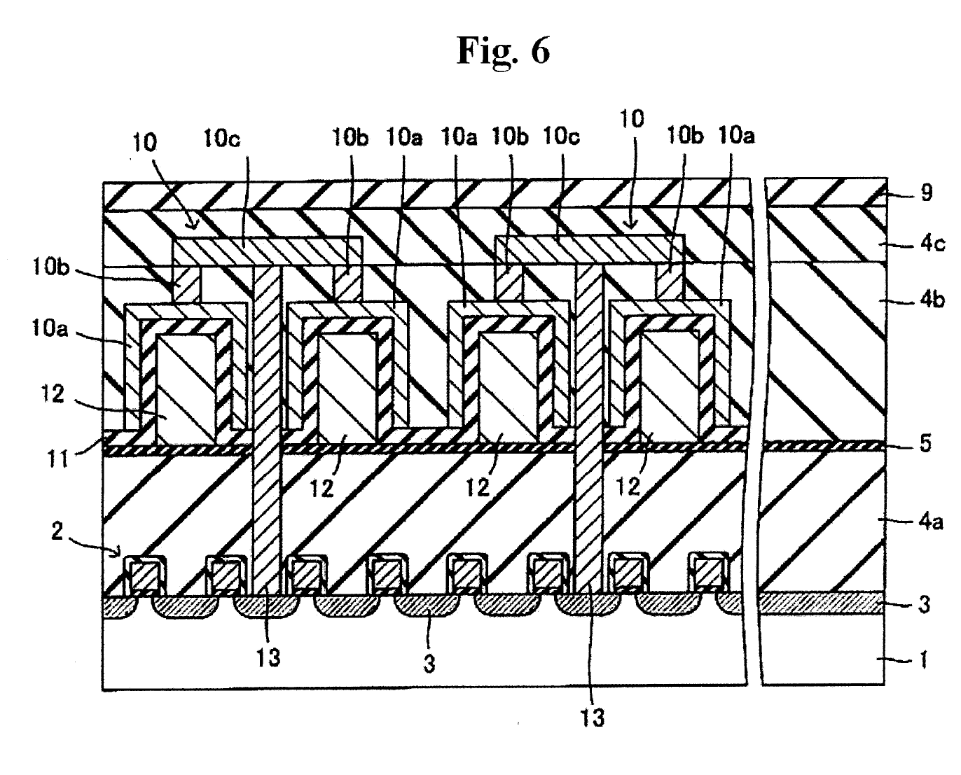

Meanwhile, the respective capacitor upper electrodes 10 do not have to be formed with a single film. For example, as shown in FIG. 6, a configuration may be employed in which conductive films 10a, each of which is formed on two adjacent capacitor lower electrodes 12, are connected to one another through plugs 10b and wiring 10c located in an interlayer insulating film 4c. Incidentally, a cross section shown in FIG. 6 corresponds to the cross section shown in FIG. 2.

### Second Embodiment

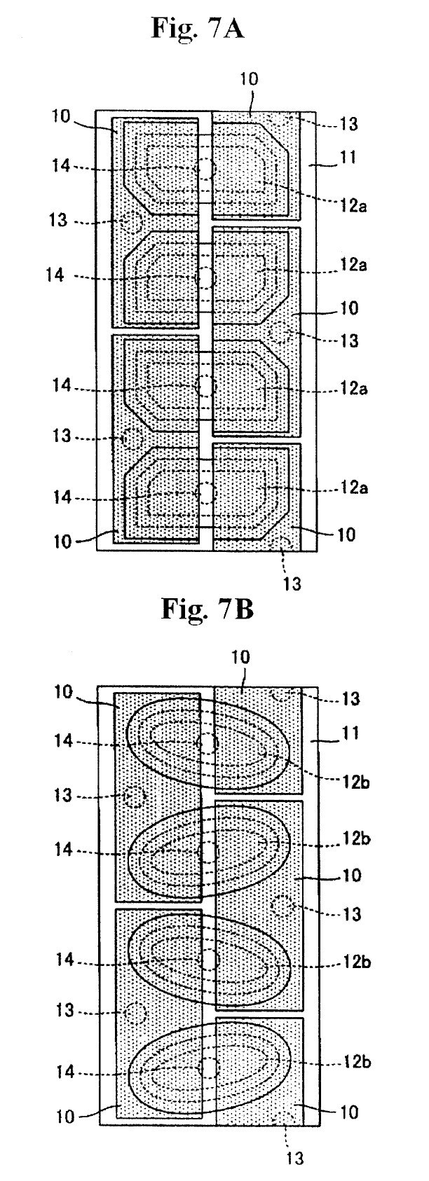

A second embodiment of the present invention will be explained hereinafter with reference to FIGS. 7A and 7B.

A second embodiment has different shapes of the capacitor lower electrodes from those in the first embodiment. Note that, explanations of the same parts as those in the first embodiment will be omitted or simplified.

(Configuration of Semiconductor Device)

FIGS. 7A and 7B are top views respectively showing capacitor structures of semiconductor devices according to the second embodiment of the present invention.

Each capacitor lower electrode 12a shown in FIG. 7A has a two-dimensional shape of a hexagon which is equivalent to the shape of the capacitor lower electrode 12 of the first embodiment after cutting off two corners that face the capacitor contacts 13. Here, the capacitor lower electrodes 12a may be formed into a polygon having six or more corners as long as such a shape is arranged to provide spaces on the sides facing the capacitor contacts 13. In the meantime, each capacitor lower electrode 12b shown in FIG. 7B has a two-dimensional shape of an oblong which is slanted so as to provide spaces on the sides facing the capacitor contacts 13.

### Effects of Second Embodiment

According to the second embodiment of the present invention, the capacitor lower electrodes 12a and 12b have the two-dimensional shapes that provide spaces on the sides facing the capacitor contacts 13. Therefore, the distance between the adjacent capacitor lower electrodes 12 can be made smaller than the diameter of the capacitor contact 13. In this way, it is possible to reduce the layout distance between the capacitor lower electrodes and to further reduce the space to be occupied by the capacitor cells.

### Third Embodiment

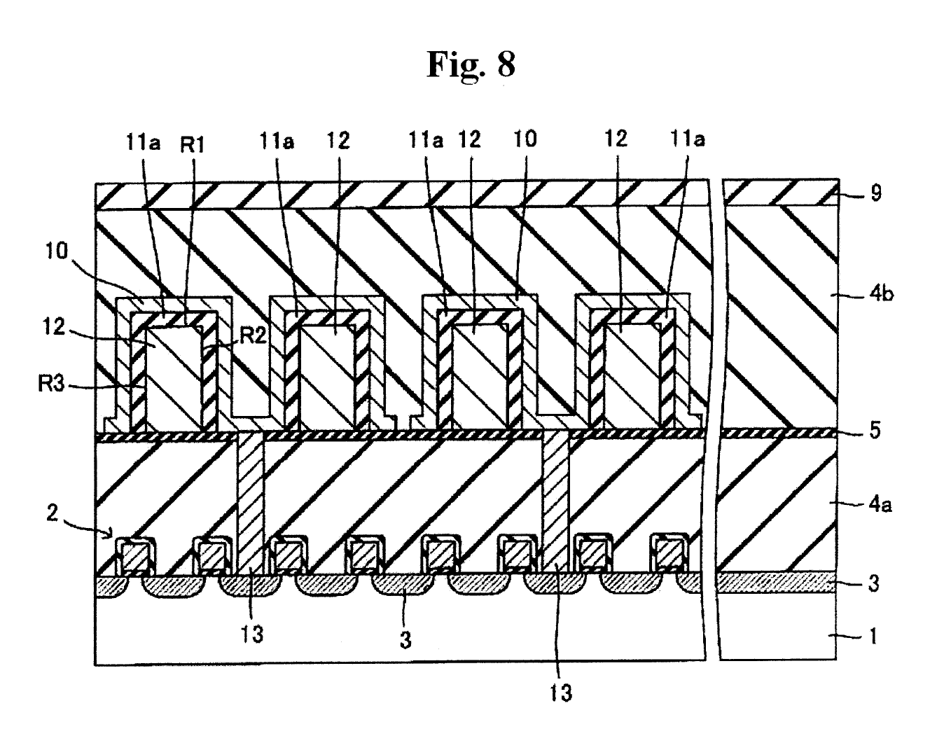

A third embodiment of the present invention will be explained hereinafter with reference to FIG. 8.

A third embodiment has a different shape of the capacitor insulating film from that in the first embodiment. Note that, explanations of the same parts as those in the first embodiment will be omitted or simplified.

(Configuration of Semiconductor Device)

FIG. 8 is a cross-sectional view of a semiconductor device according to the third embodiment of the present invention. Note that, the cross section shown in FIG. 8 corresponds to the cross section shown in FIG. 2.

A substantially entire portion on a lower surface of a capacitor insulating film 11a contacts the capacitor lower electrodes 12. Specifically, the capacitor insulating film 11a is not virtually formed in a region to contact the cap layer 5 other than the regions to contact the capacitor lower electrodes 12. Here, a surface of the capacitor insulating film 11a close to the capacitor upper electrode 10 will be defined as an upper surface while a surface on the other side close to the capacitor lower electrode 12 will be defined as a lower surface. Moreover, a surface contacting the cap layer 5 in FIG. 8 will be defined as a side surface of the capacitor insulating film 11a. Further, the capacitor insulating film 11a is formed by patterning a material film using the photolithography method, the RIE method, and the like.

### Effects of Third Embodiment

According to the third embodiment of the present invention, parasitic resistance to be applied to the capacitor contacts 13 can be reduced by rendering the region for forming the highly dielectric capacitor insulating film smaller than the area occupied in the first embodiment.

### Fourth Embodiment

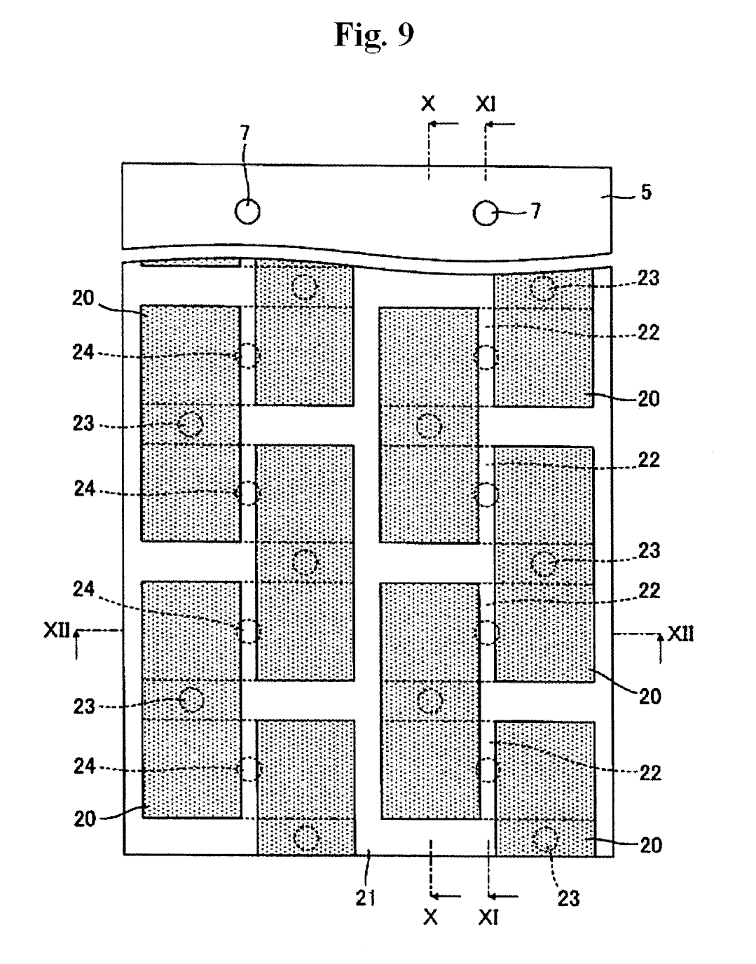

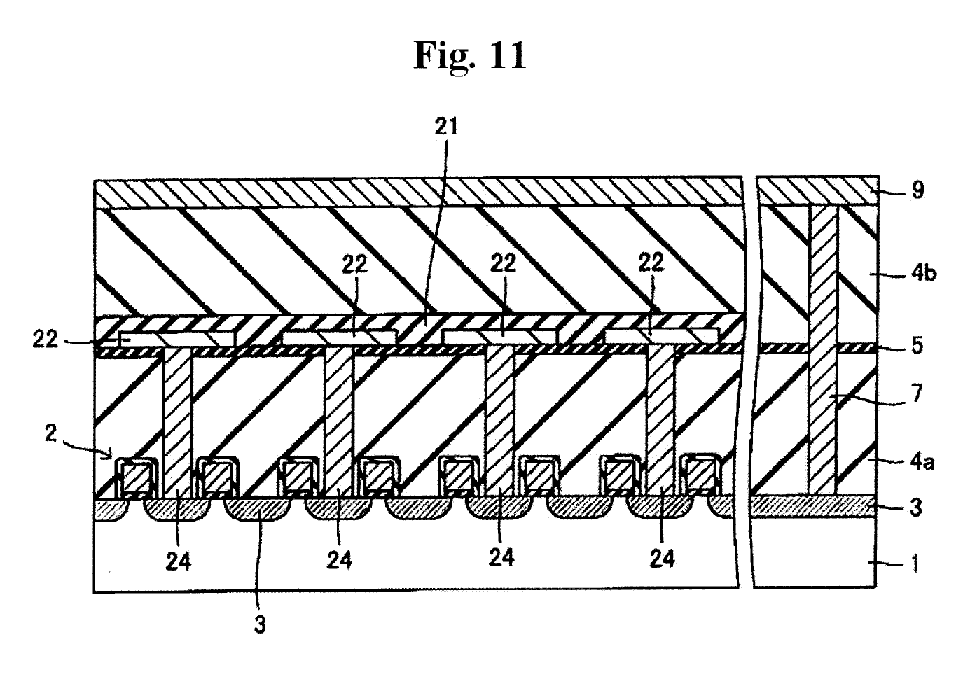

A fourth embodiment of the present invention will be explained hereinafter with reference to FIGS. 9-14.

A fourth embodiment is different from the first embodiment in that each capacitor cell has a two-dimensional structure. Note that, explanations of the same parts as those in the first embodiment will be omitted or simplified.

(Configuration of Semiconductor Device)

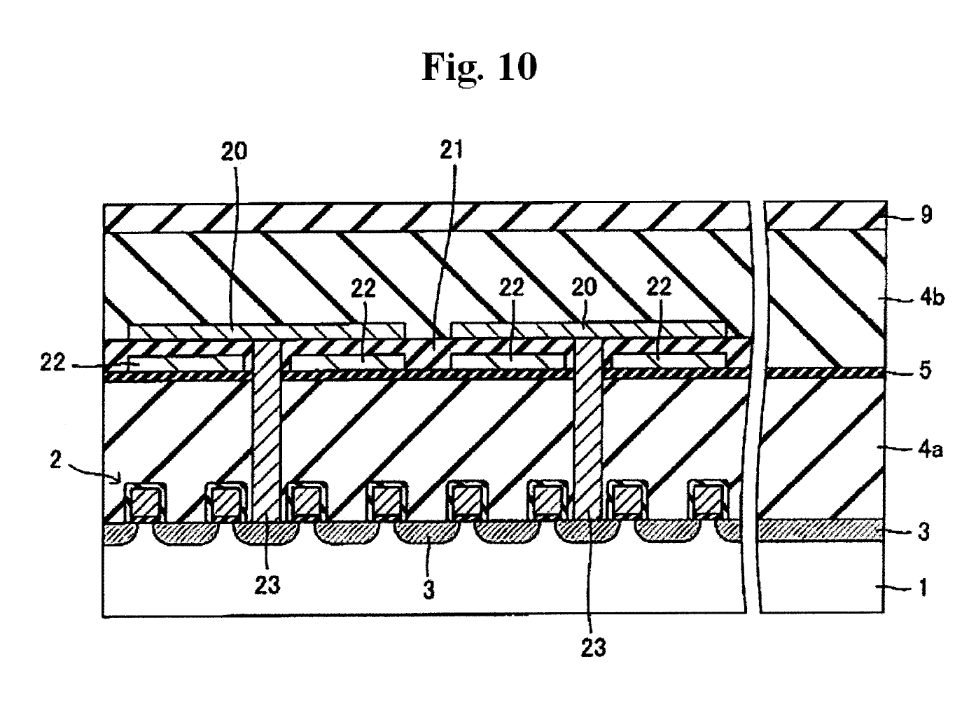

FIG. 9 is a top view showing a capacitor structure of a semiconductor device according to the fourth embodiment of the present invention. Meanwhile, FIGS. 10 to 12 are cross-sectional views showing cross sections that are respectively taken along chain lines X-X, XI-XI, and XII-XII in FIG. 1 and viewed from directions of arrows attached thereto.

A semiconductor device according to this embodiment includes: a semiconductor substrate 1; multiple transistors 2 that are arranged in series in a predetermined direction with source-drain regions 3 shared by the mutually adjacent transistors; an interlayer insulating film 4a formed on the semiconductor substrate 1 and the transistors 2; a cap layer 5 formed on the interlayer insulating film 4a; capacitor lower electrodes 22 formed on the cap layer 5; capacitor upper electrodes 20 formed on the capacitor lower electrodes 22 with a capacitor insulating film 21 interposed therebetween; capacitor contacts 23 for connecting the capacitor upper electrodes 20 to one of the source-drain regions 3; capacitor contacts 24 for connecting the capacitor lower electrodes 22 to the other one of the source-drain regions 3; an interlayer insulating film 4b formed on the cap layer 5, the capacitor upper electrodes 20, and the capacitor insulating film 11; bit lines 8 formed on the interlayer insulating film 4b and connected to drain ends of the source-drain regions 3 via bit line contacts 7; and an inter-wiring insulating film 9 formed between the bit lines 8 on the interlayer insulating film 4b.

The capacitor lower electrodes 22 include multiple electrodes that are arranged in one row at predetermined distances in a direction substantially parallel to the direction of arrangement of the transistors 2 (the vertical direction in FIG. 9). Meanwhile, a lateral direction of each of the capacitor lower electrodes 22 is preferably set substantially the same as the direction of arrangement of the capacitor lower electrodes 22. Here, the capacitor contacts 23 are formed between the mutually adjacent capacitor lower electrodes 22. Accordingly, the above-mentioned predetermined distance (the distance between the mutually adjacent capacitor lower electrodes 22) is greater than a diameter of each capacitor contact 23.

The capacitor upper electrodes 20 include multiple electrodes that are arranged on the capacitor lower electrodes 22 with the capacitor insulating film 21 interposed therebetween in two rows in a zigzag manner at predetermined distances in the direction substantially parallel to the direction of arrangement of the transistors 2 (the vertical direction in FIG. 9). Meanwhile, a direction of straight side of each of the capacitor upper electrodes 20 is preferably set substantially the same as the direction of arrangement of the capacitor upper electrodes 20.

The respective electrodes in one row out of the two rows of the capacitor upper electrodes 20 are formed above part of the electrodes disposed in a 2n-th (n is a positive integer) line and part of the electrodes disposed in a 2n?1-th line from one end out of the capacitor lower electrodes 22. Meanwhile, the respective electrodes in another row out of the two rows of the capacitor upper electrodes 20 are formed above part of the electrodes disposed in the 2n-th line and part of the electrodes disposed in a 2n+1-th line from the end out of the capacitor lower electrodes 22.

Specifically, each of the capacitor upper electrodes 20 forms each capacitor cell between the two adjacent capacitor lower electrodes 22. Meanwhile, each of the capacitor lower electrodes 22 forms each capacitor cell between the two adjacent capacitor upper electrodes 20. In this way, an array structure of the capacitor cells forms a chain structure in which the capacitor cells are connected in a zigzag manner.

Moreover, each of the capacitor upper electrodes 20 is formed partially on upper surfaces of the two adjacent capacitor lower electrodes 22 with the capacitor insulating film 21 interposed therebetween. Specifically, the capacitor upper electrode 20, the capacitor insulating film 21, and the capacitor lower electrode 22 constitute a capacitor cell having a two-dimensional structure.

The capacitor insulating film 21 is integrally formed in the entire regions on the cap layer 5 and the capacitor lower electrodes 22 within a capacitor cell region. Alternatively, the capacitor insulating film 21 may be formed only in the regions contacting the capacitor lower electrodes 22.

The capacitor contacts 23 are connected to lower surfaces of the capacitor upper electrodes 20 located between the mutually adjacent capacitor lower electrodes 22. Meanwhile, the capacitor contacts 24 are formed on lower surfaces of the capacitor lower electrodes 22.

### Effects of Fourth Embodiment

According to the fourth embodiment of the present invention, the directions of straight side of the capacitor upper electrode 20 and the capacitor lower electrode 22, which collectively constitute the capacitor cells having the two-dimensional structure, are arranged so as to define a right angle and the array structure of the capacitor cells is formed into the zigzag-shaped chain structure. In this way, both the distances between the adjacent bit line contacts 7 and the distances between the bit lines 8 can be reduced as compared with the case of employing the straight chain structure, and thereby capacitance between the bit lines can be reduced.

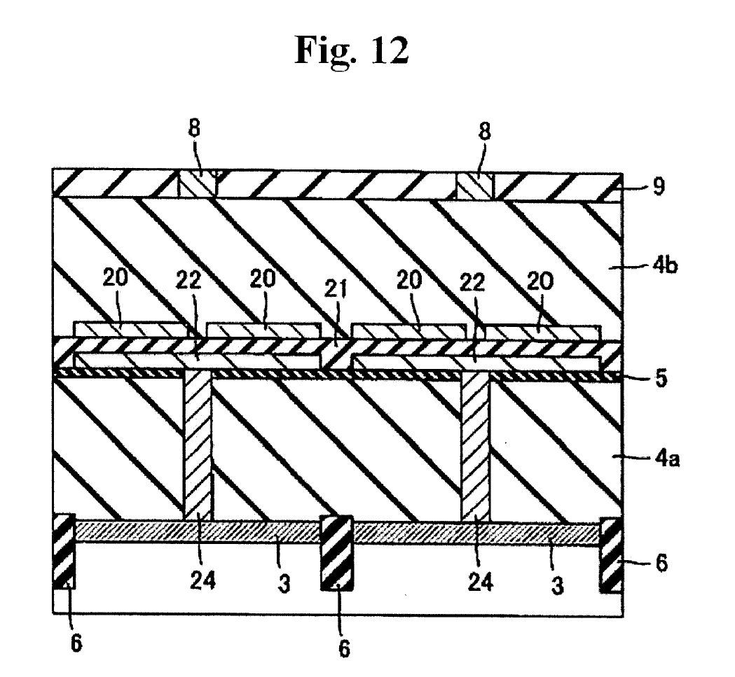

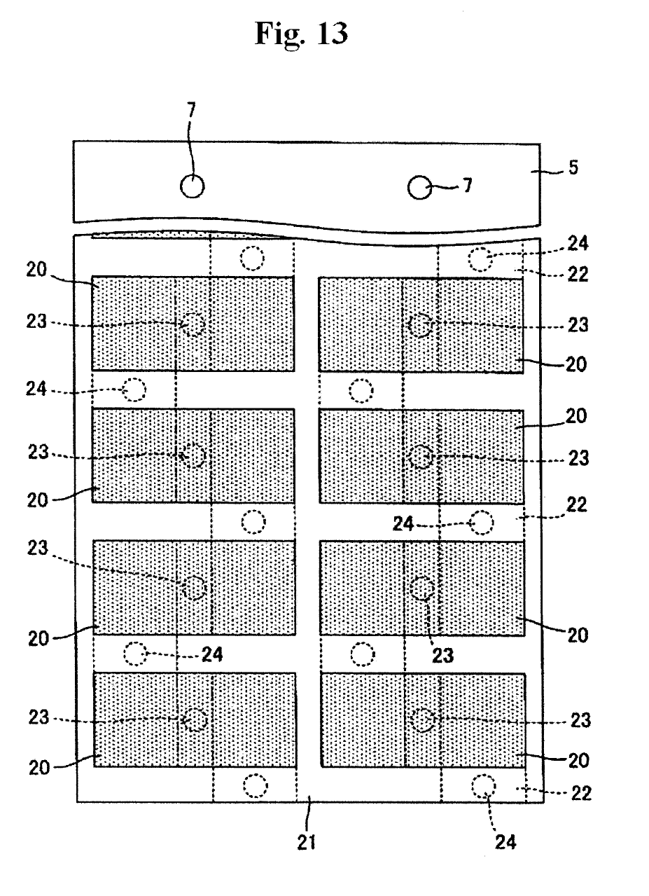

Note that, the layout correlation between the capacitor upper electrodes 20 and the capacitor lower electrodes 22 may be inverted as shown in FIG. 13. Specifically, the multiple electrodes constituting the capacitor lower electrodes 22 are arranged in two rows in a zigzag manner at predetermined distances in the direction substantially parallel to the direction of arrangement of the transistors 2 (the vertical direction in FIG. 12). Meanwhile, the multiple electrodes constituting the capacitor upper electrodes 20 are arranged in parallel in one row at predetermined distances in the direction substantially parallel to the direction of arrangement of the transistors 2 on the capacitor upper electrodes 20 with the capacitor insulating film 21 interposed therebetween. Incidentally, FIG. 13 is a top view corresponding to FIG. 9.

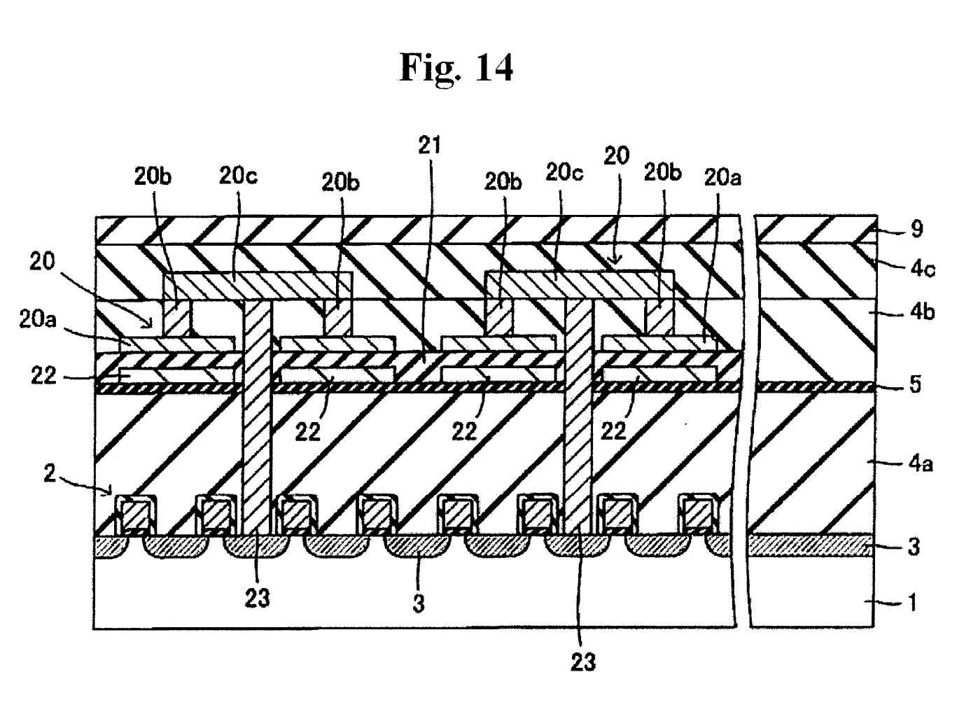

Meanwhile, the respective capacitor upper electrodes 20 do not have to be formed with a single film. For example, as shown in FIG. 14, a configuration may be employed in which conductive films 20a, each of which is formed on two adjacent capacitor lower electrodes 22, are connected to one another through plugs 20b and wiring 20c located in an interlayer insulating film 4c. Incidentally, a cross section shown in FIG. 14 corresponds to the cross section shown in FIG. 10.

Moreover, the capacitor lower electrodes 22 may have any of a hexagonal or oblong two-dimensional shape in the same manner as the capacitor lower electrodes 12a and 12b according to the second embodiment as shown in FIGS. 7A and 7B. In this way, the distance between the mutually adjacent capacitor lower electrodes 22 can be made smaller than the diameter of the capacitor contact 23, thereby reducing the layout distance between the capacitor lower electrodes and further reducing the space to be occupied by the capacitor cells.

The present invention is not limited only to the above-described embodiments. Various other embodiments are possible without departing from the scope of the invention.

Moreover, the components of the respective embodiments can be arbitrarily combined without departing from the scope of the invention.

What is claimed is:

1. A semiconductor device comprising:
a semiconductor substrate;
a plurality of transistors on the semiconductor substrate, each of the transistors has a source and drain region;
an interlayer insulating film on the semiconductor substrate and the plurality of transistors; and
at least three capacitors on the interlayer insulation film, each of them has a top electrode, a bottom electrode and an insulating film interposed therebetween;
wherein the 1st and 2nd capacitors have an shared electrode, with the top electrodes of the 1st and 2nd capacitors, which has a 1st longer direction, the 2nd and 3rd capacitors have an shared electrode, with the bottom electrodes of the 2nd and 3rd capacitors, which has a 2nd longer direction different from the 1st direction.

2. The semiconductor device according to claim 1,
wherein the bottom electrode has two-dimensional shape of a polygon having at least six angles or an oblong.

3. The semiconductor device according to claim 1,
wherein the insulating film contacts the bottom electrode at substantially entire portion of lower surface.

4. The semiconductor device according to claim 1, further comprising:
a first capacitor contact connecting electrically the bottom electrode and the source or drain region; and
a second capacitor contact connecting electrically the top electrode and another source or drain region.

5. The semiconductor device according to claim 4,
wherein the bottom electrode has two-dimensional shape of a polygon having at least six angles or an oblong.

6. The semiconductor device according to claim 5,
wherein a distance from the bottom electrode of the 2nd capacitor to the bottom electrode of the 3rd capacitor, is smaller than a diameter of the second capacitor contact.

7. The semiconductor device according to claim 1,
wherein the top electrode includes at least one of platinum, iridium, and iridium oxide.

8. The semiconductor device according to claim 1,
wherein the bottom electrode includes at least one of platinum, iridium, iridium oxide, ruthenium, and ruthenium oxide.

9. The semiconductor device according to claim 1,
wherein the at least one of the top electrode and the bottom electrode is stacked.

10. The semiconductor device according to claim 9,
wherein the top electrode includes strontium ruthenium oxide.

11. The semiconductor device according to claim 9,
wherein the bottom electrode includes iridium.

12. A semiconductor device comprising:
a semiconductor substrate;
a plurality of transistors arranged in series in a predetermined direction on the semiconductor substrate with source-drain regions shared by the mutually adjacent transistors;
an interlayer insulating film formed on the semiconductor substrate and the plurality of transistors;
a first capacitor electrode including a plurality of electrodes arranged above the interlayer insulating film in one row at predetermined distances in a direction substantially parallel to the predetermined direction;
a second capacitor electrode including a plurality of electrodes arranged above or below the first capacitor electrode with a capacitor insulating film interposed therebetween in two rows in a zigzag manner at predetermined distances in a direction substantially parallel to the predetermined direction;
a first capacitor contact connecting the first capacitor electrode to one of the source-drain regions; and
a second capacitor contact connecting the second capacitor electrode to another one of the source-drain regions, wherein
each of the electrodes in one row out of the two rows of the second capacitor electrode is formed above or below part of the 2n-th electrode and part of the 2n+1-th electrode, from one end, out of the electrodes of the first capacitor electrode, and
each of the electrodes in the other row out of the two rows of the second capacitor electrode is formed above or below part of the 2n-th electrode and part of the 2n+1-th electrode, from the one end, out of the electrodes of the first capacitor electrode, where n is a positive integer.

13. The semiconductor device according to claim 12,
wherein each of the electrodes of the capacitor electrode located on an upper side out of the first and second capacitor electrodes is formed, on upper surfaces of the two adjacent electrodes of the capacitor electrode located on a lower side, and on mutually opposed side surfaces of the two adjacent electrodes of the capacitor electrode located on the lower side, with the capacitor insulating film interposed therebetween.

14. The semiconductor device according to claim 12, further comprising:
a bit line connected to a drain end of the source-drain regions with a bit line contact interposed therebetween.

15. The semiconductor device according to claim 12,
wherein the first capacitor electrode is the electrodes located on the lower side and each having a two-dimensional shape of a polygon having at least six angles or an oblong, and
the predetermined distance between each adjacent two of the plurality of electrodes of the first capacitor electrode is smaller than a diameter of the second capacitor contact.

16. The semiconductor device according to claim 12,
wherein a substantially entire portion on a lower surface of the capacitor insulating film contacts the capacitor electrode located on the lower side out of the first and second capacitor electrodes.
